(19) United States
(12) Patent Application Publication
(10) Pub. No.: US 2020/0343656 A1
(43) Pub. Date: Oct. 29, 2020

(54) ELECTRICAL PRESS-IN CONTACT PIN

(71) Applicant: Doduco Solutions GmbH, Pforzheim (DE)

(72) Inventors: Amir Sadeghi, Pforzheim (DE); Uwe Dreissigacker, Engelsbrand (DE)

(21) Appl. No.: 16/946,896

(22) Filed: Jul. 10, 2020

Related U.S. Application Data
(63) Continuation of application No. PCT/EP2018/086128, filed on Dec. 20, 2018.

(30) Foreign Application Priority Data
Jan. 15, 2018 (DE) 10 2018 100 781.7
Apr. 17, 2018 (DE) 10 2018 109 059.5

(51) Int. Cl. H01R 12/58; H01R 4/58; H01B 1/02; H05K 1/11

(52) U.S. Cl. CPC H01R 12/585; H01R 4/58; H01B 1/026; H05K 2201/1059; H05K 2201/10189; H05K 2201/10303; H05K 1/115

(57) ABSTRACT

An electrical contact pin is intended for pressing into a hole which is provided in a circuit carrier board and has a circumferential wall with a metallized surface. The contact pin consists mainly of copper or of a copper alloy and is surrounded by a layer which includes tin at least in a part region which is to be pressed into the hole. The layer, which includes tin, forms the surface of the contact pin and includes substantially only tin and tin oxide, wherein the tin oxide is formed by way of electrolytic oxidation and the concentration thereof is greatest on the surface of the layer.

### CROSS-REFERENCE TO RELATED APPLICATIONS

This continuation application claims priority to PCT/EP2018/086128 filed on Dec. 20, 2018 which has published as WO 2019/137782 A1 and also the German application numbers 10 2018 100 781.7 filed on Jan. 15, 2018 and 10 2018 109 059.5 filed on Apr. 17, 2018, the entire contents of which are fully incorporated herein with these references.

### DESCRIPTION

### Field of the Invention

The invention refers to an electrical contact pin, which is intended to be pressed into a hole provided in a circuit carrier board, and has a circumferential wall with a metallized surface, wherein the contact pin consists primarily of copper or a copper alloy, and is surrounded by a layer containing tin.

### Background of the Invention

Such a contact pin is of known art from EP 2 596 157 B1. The use of the soft tin serves both to provide electrical contact, and also to reduce the forces required for the press-in process. However, the use of tin has the disadvantage of forming whiskers. Whiskers are single crystals that grow out of the layer containing the tin, and can then lead to electrical short circuits. To avoid this, it has been of known art to coat the contact pin with a tin-lead alloy instead of pure tin. However, lead should no longer be used because of its toxicity. EP 2 596 157 B1 therefore proposes to coat the contact pin, not with pure tin, but with a tin alloy, which contains a very high percentage, namely 30 to 72% by weight, which can be partially replaced by copper or bismuth, wherein the thickness of the alloy layer is designed to be between 0.25 μm and 0.6 μm. However, the electrolytic deposition of alloys is more complex than the electrolytic deposition of pure metals; in addition, silver is expensive and the reduction in the formation of tin whiskers that can thereby be achieved is insufficient.

This disadvantage also applies to EP 2 811 051 A1, which proposes to coat a copper contact pin first with nickel, chromium, manganese, iron or cobalt, then with up to 0.3 μm of a precious metal, and finally with up to 0.2 μm of tin or indium, or their alloy.

EP 2 195 885 B1 discloses a similar proposal. From this, for the reduction of the formation of tin whiskers, it is of known art to first apply a diffusion barrier layer of nickel to the contact pin, and then to deposit tin on the latter, or to deposit two layers of different metals, one of which is tin, and to diffuse these into each other.

From WO 2016/083198 A1 it is of known art for an electrical contact pin, made of copper or a copper-tin alloy, to be first nickel-coated, then coated with tin, and for the tin layer to be protected with a silver layer up to 5 μm thick. This procedure is expensive due to the high use of silver, and contradicts the requirement for press-in contact pins to achieve low press-in forces by means of the coating with tin.

Another complex procedure is disclosed by WO 2011/056698 A2, which proposes to deposit an alloy of tin and silver on a copper substrate so as to reduce the formation of tin whiskers.

WO 2009/117639 A2 discloses a similar procedure. From this it is of known art, instead of using pure tin, to coat press-fit contact pins with an alloy of tin and silver, and possibly other additives such as bismuth, silicon, magnesium, iron, manganese, tungsten or antimony, with a layer thickness of up to 4 μm.

WO 2011/047953 A1 proposes to coat tinned press-fit contact pins with an organic protective layer, which is designed to prevent an oxidation of the tin.

WO 2012/049297 A1 discloses electrical press-fit contact pins in which the use of tin is completely dispensed with, and the contact pin is instead coated with an indium alloy, which is tin-free, and in addition can be protected by an organic protective layer.

### SUMMARY OF THE INVENTION

An object underlying the present invention is that of creating an electrical press-fit contact pin, which has a core of copper or a copper alloy, and is surrounded by a layer containing tin, and can be produced with less effort than press-fit contact pins of known art, requires no use of precious metal, is insensitive to oxidation, can be pressed into a hole in a circuit carrier board with moderate force, and, when pressed in, has a low contact transfer resistance, as can be achieved with pure tin.

This object is achieved by an electrical contact pin with the features specified in claim 1. Advantageous refinements of the invention are the subject matter of dependent claims.

The press-fit contact pin according to the invention consists primarily of copper or a copper alloy, and is surrounded, at least in a region, which is intended to be pressed into a hole of a circuit carrier board, by a layer containing tin, which forms the surface of the contact pin in the region to be pressed in, and contains essentially only tin and tin oxide, wherein the tin oxide is formed by electrolytic oxidation, and its concentration is highest at the surface of the layer.

This design of the press-fit contact pin has significant advantages:
The tin to be deposited on the contact pin does not have to contain any alloying constituents.
As the tin does not have to contain any alloying constituents, no complex deposition process is required. Rather, the tin can be deposited from an electrolytic bath of well-known art, for example from an acidic electrolytic bath, which contains the tin as tin-II-methane sulphonate.
Even without the addition of any alloying elements, the electrolytically oxidised tin layer hinders the growth of tin whiskers out of the layer as a result of complementary effects: Firstly, the oxidised tin cannot be the starting point for the growth of a tin whisker. On the other hand, any non-oxidised tin is located in the lower region of the layer, so that a tin whisker emanating from there must pass through the material located above before it can emerge from the surface of the layer and intrude. Thirdly, the tin oxide concentrated on the surface of the coating forms a barrier against the growth of tin whiskers.
Surprisingly, it has been shown that the electrolytic oxidation of the tin layer does not lose the advantage of a pure tin layer, namely that of making it easier to press the contact pin into a hole in a printed circuit board. The force required to press in an inventive contact pin does not differ essentially from the force required to press in the same contact pin before electrolytic oxidation of its tin layer.
Although the electrical conductivity of tin oxide has at most the value of the conductivity of a semiconductor, a low electrical contact resistance is achieved with an inventive press-fit contact pin when pressed into a hole in a circuit carrier board because the oxidised tin layer is abraded by the press-fit process, as a result of which the desired metallic contact is made between the contact pin and the wall of the hole in the circuit carrier board, and cold welding occurs between the contact pin and the wall of the hole in the circuit carrier board.

The thickness of the layer containing tin can be kept small. A lower limit of the layer thickness results from the requirement that the layer is still capable of adequately reducing the force required to press in the contact pin, compared to that for an uncoated contact pin. At the same time, the tin oxide layer should be thick enough so as to ensure that the risk of any tin whiskers growing out is low. The thickness of the layer containing the tin should preferably be at least 0.2 μm, in particular 0.5 μm. Furthermore the thickness of the layer containing the tin should preferably be 1 μm to 3 μm, in particular 1.5 μm to 2.5 μm. Good results have been achieved with a layer thickness of approx. 2 μm.

Surprisingly, it has been shown that even the conversion of the majority of the tin to tin oxide does not eliminate the suitability of the contact pin as a press-fit contact pin. Preferably, 50 mol % to 80 mol % of tin is converted into tin oxide by the electrolytic oxidation.

In the production of the inventive contact pin, the tin layer is preferably electrolytically oxidised to such an extent that the layer has only tin oxide on its surface, and is preferably dense. This can easily be achieved with a conversion of at least half of the tin to tin oxide.

The tin with which the electrical contact pin is coated should preferably be of technical purity. In an unused state the inventive contact pin then contains only tin and oxygen in the layer containing the tin, apart from usual or production-related impurities.

A major cause for the formation of tin whiskers could be that, from the copper or copper alloy, of which the contact pin essentially consists, copper diffuses into the layer containing tin, and there forms an intermetallic compound of tin and copper, which could be the trigger for the growth of whiskers in the layer. A diffusion-inhibiting intermediate layer, which preferably consists of nickel or silver, is therefore preferably provided between the layer containing the tin and the copper or copper alloy, of which the contact pin primarily consists. By the combination of an electrolytically oxidised tin layer above a diffusion-inhibiting intermediate layer on a press-fit contact pin consisting primarily of copper or a copper alloy, the growth of tin whiskers from the electrolytically oxidised tin layer can be completely prevented.

The diffusion-inhibiting intermediate layer need not be thicker than 4 μm. Good results are achieved with an intermediate layer thickness of 1.5 μm to 2.5 μm. Its thickness is preferably 2 μm or less.

As the copper alloy, of which the inventive contact pin can primarily consist, a binary copper alloy with 4 to 8% by weight of tin, in particular with 6% by weight of tin, is particularly suitable.

The electrolytic oxidation of the tin is preferably carried out in such a way that the tin oxide is predominantly present as SnO-II-oxide (SnO). For this purpose it is recommended that the electrolytic oxidation be executed in an alkaline bath in which the contact pin is connected as the anode. The electrolytic oxidation should be carried out in such a way that at least on the surface, and near the surface, of the layer containing the tin oxide, the SnO predominates over the SnO₂. Preferably it is only SnO that is present on the surface of the layer containing the tin oxide.

### BRIEF DESCRIPTION OF THE DRAWINGS

In what follows an example of embodiment of the invention is described with the aid of the accompanying figures.

FIG. 1 is a schematic representation of a detail of a circuit carrier board in a cross-section at right angles to the surface of the circuit carrier board, with a cross-section of a press-fit contact pin, once before it is pressed in, and once after it is pressed into a hole in the circuit carrier board, and

FIG. 2 shows schematically, and in a much magnified manner, a possible layered structure on a press-fit contact pin in accordance with the invention.

### DETAILED DESCRIPTION OF THE PREFERRED EMBODIMENTS

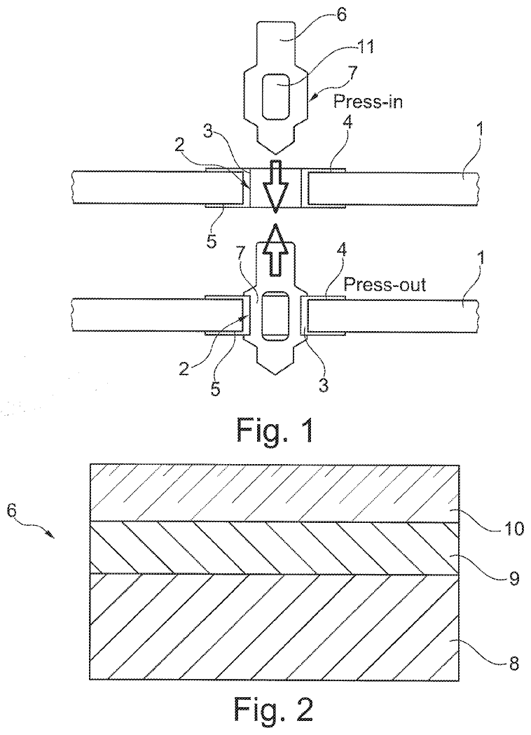

FIG. 1 shows a cross-section through a part of a circuit carrier board 1, in which a hole 2 is provided, the circumferential wall of which is metallized and has, for example, a copper layer 3, which covers not only the circumferential wall of the hole 2, but also adjacent regions 4 on the upper face and 5 on the lower face of the circuit carrier board 1. The contact pin 6 is tapered and has a recess 11 near its lower end, which allows an extended region 7 surrounding the recess 11 to be compressed. This happens when the contact pin 6 is pressed into the hole 2; see the lower illustration in FIG. 1. The compression of the extended region 7 of the contact pin 6, and the resulting friction of the contact pin 6 against the metallized wall of the hole 2, causes the electrolytically oxidised tin layer located on the extended region 7 of the contact pin 6 to be abraded. Abrasion of the oxidised tin layer also causes the cold welding of the contact pin 6 to the metallized wall of the hole 2.

FIG. 2 shows an example of a layered structure of an inventive contact pin 6: On the base body 8 of the contact pin 6, at least in the extended region 7 according to FIG. 1, there is located a diffusion-inhibiting intermediate layer 9 of nickel, and a layer 10 containing tin, which are both, for example, 2 μm thick.

Before the deposition of the diffusion-inhibiting intermediate layer 9 on contact pins 6 made of CuSn6, these were first chemically degreased, and then electrochemically degreased in an alkaline solution. After a washing process, the contact pins 6 were coated with 2 μm of nickel in an acidic electrolytic bath based on nickel-methane sulphonate. The nickel-coated contact pins 6 were then activated in a dilute methane sulphonic acid and then coated with 2 μm tin in an acidic electrolyte based on tin-II-methane sulphonate.

The electrolytic oxidation of the tin took place in the alkaline solution, also used for electrochemical degreasing, with a contact pin connected as the anode, at a DC voltage of 5 V to 10 V, for a period of 10 seconds to 30 seconds, wherein oxidation took place for 30 seconds at 5 V, and 10 seconds at 10 V. A subsequent investigation showed that approximately 70 mol % of the tin was then oxidised. The oxidation progressing during the electrolytic treatment was illustrated by a progressive discolouration of the surface of the tin layer, from the original light grey metallic tin to a dark blue colour, which is characteristic for the formation of SnO.

The progression of the oxidation from the surface into the tin layer is indicated in FIG. 2, in that the density of the hatching in the layer 10 increases from the lower interface with the nickel layer 9 to the surface, wherein the density of the hatching is not true to scale, and has only a symbolic meaning.

With contact pins coated in this way, press-in and press-out forces were measured and compared to press-in and press-out forces with contact pins coated with nickel and non-oxidised tin. When press-fitted into a hole in a circuit carrier board at a speed of 25 mm/min, a press-fit force of 65 N was measured for a contact pin without an electrolytic oxidation of the tin, and a press-fit force of 66 N was measured when using a press-fit pin with an electrolytically oxidised tin.

The extraction force when pulling the contact pin out of the hole in the circuit carrier board was measured after the contact pin had been sitting in the circuit carrier board 1 for 24 hours. The extraction force was measured at an extraction speed of 10 mm/min. A force of 78 N was measured when extracting a contact pin without electrolytically oxidised tin, and a force of 80 N was measured when extracting a contact pin with electrolytically oxidised tin. Accordingly, there were no significant differences in the extraction forces between contact pins for which the tin was not oxidised and contact pins for which the tin was electrolytically oxidised.

### LIST OF REFERENCE SYMBOLS

1 Circuit carrier board
2 Hole
3 Copper layer
4 Region on the upper face
5 Region on the lower face
6 Contact pin
7 Extended region
8 Base body
9 Diffusion-inhibiting intermediate layer
10 Layer containing tin
11 Recess

What is claimed is:

1. An electrical contact pin configured to be pressed into a hole of a circuit carrier board, the hole having a circumferential wall with a metallized surface;
wherein the contact pin consists primarily of copper or a copper alloy, and is surrounded by a layer containing tin, at least in a region to be pressed into the hole;
wherein the layer containing the tin forms a surface of the contact pin, and contains essentially only tin and tin oxide, wherein the tin oxide is formed by electrolytic oxidation, and its concentration is highest at the surface of the layer.

2. The electrical contact pin according to claim 1, wherein the layer containing tin has a thickness of at least 0.2 μm.

3. The electrical contact pin according to claim 1, wherein the layer containing tin has a thickness of at least 0.5 μm.

4. The electrical contact pin according to claim 1, wherein the layer containing tin has a thickness of 1 μm to 3 μm.

5. The electrical contact pin according to claim 1, wherein the thickness of the layer containing tin is 1.5 μm to 2.5 μm.

6. The electrical contact pin according to claim 1, wherein 50 mol % to 80 mol % of tin is present as tin oxide.

7. The electrical contact pin according to claim 1, wherein the layer containing the tin contains only tin oxide at the surface.

8. The electrical contact pin according to claim 1, wherein in the unused state of the contact pin the layer containing the tin contains only tin and oxygen apart from usual or production-related impurities.

9. The electrical contact pin according to claim 1, wherein a diffusion-inhibiting intermediate layer is provided between the layer containing the tin and the core.

10. The electrical contact pin according to claim 9, wherein the diffusion-inhibiting intermediate layer consists of nickel or silver.

11. The electrical contact pin according to claim 9, wherein the diffusion-inhibiting intermediate layer is not thicker than 4 μm.

12. The electrical contact pin according to claim 9, wherein the diffusion-inhibiting intermediate layer is 1.5 μm to 2.5 μm thick.

13. The electrical contact pin according to claim 9, wherein the diffusion-inhibiting intermediate layer is 2 μm thick.

14. The electrical contact pin according to claim 1, wherein it consists primarily of a binary copper alloy with 4 to 8% by weight of tin.

15. The electrical contact pin according to claim 1, wherein it consists primarily of a binary copper alloy with 6% by weight of tin.

16. The electrical contact pin according to claim 1, wherein the tin oxide is primarily present as SnO.

17. The electrical contact pin according to claim 16, wherein in the layer containing the tin, at least at the surface and in the vicinity of the surface of the layer containing the tin, SnO predominates over SnO₂ by volume.

18. The electrical contact pin according to claim 16, characterised in that the tin oxide is exclusively present as SnO.

19. An electrical press-in contact pin assembly, comprising:
an electrical contact pin;
a circuit carrier board having a hole, the hole having a circumferential wall with a metallized surface;
wherein the electrical contact pin is configured to be pressed into the hole of the circuit carrier board;
wherein the contact pin consists primarily of copper or a copper alloy, and is surrounded by a layer containing tin, at least in a region to be pressed into the hole;
wherein the layer containing the tin forms a surface of the contact pin, and contains essentially only tin and tin oxide, wherein the tin oxide is formed by electrolytic oxidation, and its concentration is highest at the surface of the layer.
